(19) United States
(12) Patent Application Publication
(10) Pub. No.: US 2013/0256788 A1
(43) Pub. Date: Oct. 3, 2013

(54) SEMICONDUCTOR DEVICE

(71) Applicant: ELPIDA MEMORY, INC., Tokyo (JP)

(72) Inventor: Yu KOSUGE, Tokyo (JP)

(73) Assignee: ELPIDA MEMORY, INC., Tokyo (JP)

(21) Appl. No.: 13/787,891

(22) Filed: Mar. 7, 2013

(30) Foreign Application Priority Data
Mar. 27, 2012 (JP) 2012-071232

(51) Int. Cl. H01L 29/78

(52) U.S. Cl. CPC H01L 29/7827
USPC 257/330

(57) ABSTRACT

A semiconductor device comprises an isolation region formed by filling a trench with an insulator, an active region surrounded with the sidewall of the trench, a combined pillar including a semiconductor pillar in the active region and an insulator pillar in the isolation region, a gate electrode covering a side surface surrounding the combined pillar; and a transistor including the combined pillar and the gate electrode. The trench has a sidewall in a semiconductor substrate. The insulator pillar contacts the semiconductor pillar with the sidewall of the trench interposed therebetween.

This application is based upon and claims the benefit of priority from Japanese Patent Application No. 2012-71232 filed on Mar. 27, 2012, the disclosure of which is incorporated herein in its entirety by reference.

### BACKGROUND OF THE INVENTION

1. Field of the Invention

The present invention relates to a semiconductor device.

2. Description of the Related Art

Improvement in the degree of integration of a semiconductor device has been achieved primarily by miniaturization of a transistor. Miniaturization of a transistor is approaching a limit, and further reduction in size of a transistor may result in malfunction due, for example, to a short channel effect.

As a fundamental solution to the problem described above, there are proposed methods for processing a semiconductor substrate three-dimensionally to form a transistor three-dimensionally. Among transistors formed by using these methods, a vertical transistor having a three-dimensional structure in which a semiconductor pillar extending perpendicular to a principal plane of a semiconductor substrate is used as a channel has an advantage of a small footprint and a large amount of drain current achieved by complete depletion.

FIGS. 24A and 24B are schematic views of a major portion of a vertical transistor described in JP2008-300623A. FIG. 24A is a plan view, and FIG. 24B is a cross-sectional view taken along line B-B in FIG. 24A. Isolation region 51 formed in silicon semiconductor substrate 50 and active region 52 formed of silicon substrate 50 surrounded with isolation region 51 are provided, and first semiconductor pillar 53 and second semiconductor pillar 54 adjacent to first semiconductor pillar 53 are disposed in active region 52. The semiconductor pillars are formed by digging silicon substrate 50 in active region 52 downward from the surface of silicon substrate 50.

Lower oxide film 56 is formed on the upper surface of active region 52 except first semiconductor pillar 53 and second semiconductor pillar 54. Below lower oxide film 56 (in lower portions of semiconductor pillars), lower diffusion layer 57 is formed so that it surrounds semiconductor pillars 53 and 54. LDD diffusion layer 58 is formed in an upper portion of first semiconductor pillar 53, and stacked diffusion layer 60 formed of a stacked silicon layer is disposed on LDD diffusion layer 58. Insulator 59 is formed on the circumferential side surfaces of stacked diffusion layer 60. LDD diffusion layer 58 and stacked diffusion layer 60 form an upper diffusion layer. First gate electrode 55a is formed on a circumferential side surface of first semiconductor pillar 53 with a gate insulator (not shown) interposed therebetween.

On the other hand, insulator 61 is disposed on the upper surface of second semiconductor pillar 54, and no upper diffusion layer is formed therein. Second gate electrode 55b is formed on a side surface of second semiconductor pillar 54 with a gate insulator (not shown) interposed therebetween. Second gate electrode 55b and first gate electrode 55a are connected to each other by filling the space between pillars 53 and 54. Since no upper diffusion layer is formed in second semiconductor pillar 54, second semiconductor pillar 54 does not function as a transistor. First interlayer insulating film 62 is formed so that it covers first semiconductor pillar 53 and second semiconductor pillar 54, and second interlayer insulating film 63 is further formed on first interlayer insulating film 62.

Contact plug 64 connected to lower diffusion layer 57 is formed through second interlayer insulating film 63 and first interlayer insulating film 62. Further, contact plug 65 connected to the upper diffusion layer is formed through second interlayer insulating film 63. Moreover, contact plug 66 connected to second gate electrode 55b is formed through second interlayer insulating film 63 and part of first interlayer insulating film 62. The upper surfaces of the contact plugs are connected to each other with wiring lines. There is disclosed a vertical transistor formed of lower diffusion layer 56, upper diffusion layer 58 (60), and gate electrode 55a, which covers the circumferential side surface of first semiconductor pillar 53 with the gate insulator interposed threrebetween.

In the vertical transistor described in JP2008-300623A, electric power is fed to first gate electrode 55a on first semiconductor pillar 53, which functions as a transistor, through contact plug 66 and a wiring line connected to first gate electrode 55a via second gate electrode 55b formed on a side surface of second semiconductor pillar 54 adjacent to the first semiconductor pillar 53. Contact plug 66 is formed by forming a contact hole in such a way that the upper end surface of second gate electrode 55b is exposed through second interlayer insulating film 63 and part of first interlayer insulating film 62 and filling the contact hole with a conductor. The contact hole is formed in a dry etching process. If a contact hole pattern that works as a mask in the dry etching process is shifted from the upper end surface of second gate electrode 55b, the formed contact hole disadvantageously passes through first interlayer insulating film 62 and reaches lower diffusion layer 57 as shown in FIG. 24B. As a result, contact plug 66 and lower diffusion layer 57 form a short circuit, which is problematic because the transistor is unable to operate.

### SUMMARY OF THE INVENTION

In one embodiment, there is provided a semiconductor device comprising:

an isolation region formed by filling a trench with an insulator, the trench having a sidewall in a semiconductor substrate;

an active region surrounded with the sidewall of the trench;

a combined pillar including a semiconductor pillar in the active region and an insulator pillar in the isolation region, the insulator pillar contacting the semiconductor pillar with the sidewall of the trench interposed therebetween;

a gate electrode covering a side surface surrounding the combined pillar; and

a transistor including the combined pillar and the gate electrode.

In another embodiment, there is provided a semiconductor device comprising:

an isolation region formed by filling a trench with an insulator, the trench having a sidewall in a semiconductor substrate;

an active region surrounded with the sidewall of the trench;

a first combined pillar including a first semiconductor pillar in the active region and a first insulator pillar in the isolation region, the first insulator pillar contacting the first semiconductor pillar with the sidewall of the trench interposed therebetween;

a first gate electrode covering a side surface surrounding the first combined pillar;

a first transistor including the first combined pillar and the first gate electrode;

a second combined pillar including a second semiconductor pillar in the active region and a second insulator pillar in the isolation region, the second insulator pillar contacting the second semiconductor pillar with the sidewall of the trench interposed therebetween;

a second gate electrode covering a side surface surrounding the second combined pillar; and

a second transistor including the second combined pillar and the second gate electrode,

wherein the first transistor and the second transistor face each other with approximate symmetry against a centerline that places a same distance from both of the first and second semiconductor pillars.

In another embodiment, there is provided a semiconductor device comprising:

an isolation region formed by filling a trench with an insulator, the trench having a sidewall in a semiconductor substrate;

a first active region surrounded with the sidewall of the trench;

a second active region surrounded with the sidewall of the trench;
a combined pillar including a first semiconductor pillar in the first active region, a second semiconductor pillar in the second active region, and an insulator pillar in the isolation region that is provided between the first and second semiconductor pillars;

a gate electrode covering a side surface surrounding the combined pillar; and

a transistor including the combined pillar and the gate electrode,
wherein both sides of the insulator pillar contact each of the first and second semiconductor pillars with the sidewall of the trench interposed therebetween.

### BRIEF DESCRIPTION OF THE DRAWINGS

The above features and advantages of the present invention will be more apparent from the following description of certain preferred embodiments taken in conjunction with the accompanying drawings, in which:

FIGS. 1A to 1D show a semiconductor device according to a first exemplary embodiment;

FIG. 2 shows a method for manufacturing the semiconductor device according to the first exemplary embodiment;

FIG. 3 shows the method for manufacturing the semiconductor device according to the first exemplary embodiment;

FIG. 4 shows the method for manufacturing the semiconductor device according to the first exemplary embodiment;

FIG. 5 shows the method for manufacturing the semiconductor device according to the first exemplary embodiment;

FIG. 6 shows the method for manufacturing the semiconductor device according to the first exemplary embodiment;

FIG. 7 shows the method for manufacturing the semiconductor device according to the first exemplary embodiment;

FIG. 8 shows the method for manufacturing the semiconductor device according to the first exemplary embodiment;

FIG. 9 shows the method for manufacturing the semiconductor device according to the first exemplary embodiment;

FIG. 10 shows the method for manufacturing the semiconductor device according to the first exemplary embodiment;

FIGS. 11A and 11B show a semiconductor device according to a second exemplary embodiment;

FIG. 12 shows a method for manufacturing the semiconductor device according to the second exemplary embodiment;

FIG. 13 shows the method for manufacturing the semiconductor device according to the second exemplary embodiment;

FIG. 14 shows the method for manufacturing the semiconductor device according to the second exemplary embodiment;

FIG. 15 shows the method for manufacturing the semiconductor device according to the second exemplary embodiment;

FIG. 16 shows the method for manufacturing the semiconductor device according to the second exemplary embodiment;

FIGS. 17A and 17B show a state in which transistors are connected in parallel to each other;

FIGS. 18A and 18B show a state in which transistors are connected serially to each other;

FIG. 19 shows an example of transistor arrangement;

FIG. 20 shows another example of transistor arrangement;

FIG. 21 shows a semiconductor device according to a third exemplary embodiment;

FIGS. 22A and 22B show semiconductor devices according to a fourth exemplary embodiment;

FIG. 23 shows a semiconductor device according to a fifth exemplary embodiment; and

FIGS. 24A and 24B show a semiconductor device described in JP2008-300623A.

In the drawings, numerals have the following meanings: 1: silicon substrate, 1a: substrate surface, 2: isolation region, 2a: sidewall, 2b: trench, 2e: upper surface of isolation region, 3, 3a1, 3b1, 3c1, 3d1, 3e1, 3f1: active region, 3a, 3b, 3c, 3d, 3ac, 3ba: side surface of active region, 4: pad oxide film, 5: silicon nitride film, 5a: mask nitride film, 5b: upper surface of mask nitride film, 5c: sidewall, 5d: opening, 6, 6a1, 6b1: semiconductor pillar, 6a, 6b, 6c, 6d, 6aa, 6ab, 6ac, 6ad, 6ba, 6bb, 6bc, 6bd: side surface of semiconductor pillar, 6e: bottom surface of semiconductor pillar, 7, 7a1, 7b1: insulator pillar, 7a, 7b, 7c, 7d: side surface of insulator pillar, 8, 8a, 8b: combined pillar, 9: first sidewall nitride film, 10: lower oxide film, 11: lower diffusion layer, 12, 12a, 12b: gate insulator, 13, 13a1, 13b1: gate electrode, 13a: sidewall amorphous silicon film, 13b: upper end surface of sidewall amorphous silicon film, 14: first interlayer insulating film, 14a: upper surface of first interlayer insulating film, 15, 15a, 15b: LDD diffusion layer, 16: sidewall insulating film, 17, 17a, 17b: stacked diffusion layer, 17c, 17d: upper diffusion layer, 18: upper diffusion layer, 19: second interlayer insulating film, 20a: first contact hole, 20b: second contact hole, 20c: third contact hole, 21, 21a, 21b, 22, 22a, 22b, 23, 23a, 23b: contact plug, 24: wiring line, 25: extending direction of combined pillar, 31, 33: input wiring line, 31a, 31b, 33a, 33b: wiring line, 32, 34: output wiring line, 50: silicon semiconductor substrate, 51: isolation region, 52: active region, 53: first semiconductor pillar, 54: second semiconductor pillar, 55a: first gate electrode, 55b: second gate electrode, 56: lower oxide film, 57: lower diffusion layer, 58: LDD diffusion layer, 59, 61: insulator, 60: stacked diffusion layer, 62: first interlayer insulating film, 63: second interlayer insulating film, 64, 65, 66: contact plug, D1: depth of isolation region, D2: depth from substrate surface to bottom surface of semiconductor pillar, Tr1: first vertical transistor, Tr2: second vertical transistor, W1: width of active region in direction Y, W2: width of insulator pillar in direction Y, W3: width of semiconductor pillar in direction Y, W4: width of first semiconductor pillar in direction X, W5: width of second semiconductor pillar in direction X.

### DETAILED DESCRIPTION OF THE PREFERRED THE EMBODIMENTS

In the following description, a direction 25 in which a combined pillar extends, is referred to as “direction X” and a direction perpendicular to direction 25 in which a combined pillar extends is referred to as “direction Y”.

The invention will be now described herein with reference to illustrative embodiments. Those skilled in the art will recognize that many alternative embodiments can be accomplished using the teachings of the present invention and that the invention is not limited to the embodiments illustrated for explanatory purposes.

### First Exemplary Embodiment

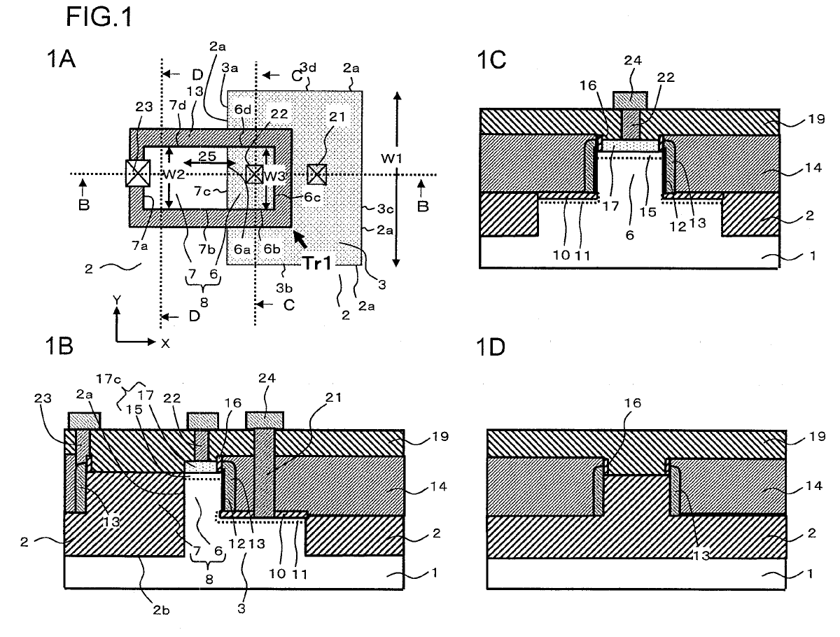

FIGS. 1A to 1D show the structure of a semiconductor device according to an exemplary embodiment. FIG. 1A is a plan view. FIG. 1B is a cross-sectional view taken along line B-B in FIG. 1A. FIG. 1C is a cross-sectional view taken along line C-C in FIG. 1A. FIG. 1D is a cross-sectional view taken along line D-D in FIG. 1A.

The semiconductor device according to the exemplary embodiment is a vertical transistor using combined pillar 8, which is a combination of semiconductor pillar 6 and insulator pillar 7, and active region 3 surrounded with isolation region 2 is provided, as shown in FIGS. 1A to 1D. That is, isolation region 2 is formed by filling trench 2b including sidewall 2a with an insulator. Active region 3 is surrounded with sidewall 2a of trench 2b. Active region 3 has, but not necessarily, a rectangular shape including side surfaces 3a and 3c facing each other in direction X and side surfaces 3b and 3d facing each other in direction Y. First semiconductor pillar 6 is disposed in silicon substrate 1 in active region 3 and in contact with one side surface 3a of active region 3. First semiconductor pillar 6 has, but not necessarily, a rectangular shape including side surfaces 6a and 6c facing each other in direction X and side surfaces 6b and 6d facing each other in direction Y.

First insulator pillar 7, which is formed of the insulator that forms isolation region 2, is disposed in isolation region 2 that is in contact with one side surface 3a of active region 3. First insulator pillar 7 has, but not necessarily, a rectangular shape including side surfaces 7a and 7c facing each other in direction X and side surfaces 7b and 7d facing each other in direction Y. First insulator pillar 7 is in contact with side surface 6a of first semiconductor pillar 6 at one side surface 3a of the active region. That is, first insulator pillar 7 is in contact with first semiconductor pillar 6 with sidewall 2a of trench 2b interposed therebetween. First combined pillar 8, which is a combination of first semiconductor pillar 6 and first insulator pillar 7, therefore extends in active region 3 and isolation region 2. Width W2 of first insulator pillar 7 in direction Y (direction perpendicular to direction 25 in which combined pillar extends) is equal to width W3 of first semiconductor pillar 6 in direction Y. Width W2 is, however, not necessarily equal to width W3 and may be wider or narrower than width W3. The width of first insulator pillar 7 in direction X, which is not limited to a specific value, is preferably a value that prevents contact plug 23 formed on gate electrode 13 from being in contact with semiconductor pillar 6, that is, at least half the width of contact plug 23 in direction X. Further, width W3 of first semiconductor pillar 6 in direction Y is shorter than the length of one side surface 3a of active region 3, that is, narrower than width W1 of active region 3 in direction Y. Width W3 is not necessarily set as described above and may be equal to width W1.

Lower oxide film 10 is formed on the upper surface of active region 3 except first semiconductor pillar 6. Further, lower diffusion layer 11, which forms one of source/drain diffusion layers of the vertical transistor, is formed in the surface of silicon substrate 1 located below lower oxide film 10 (lower portion of active region 3).

LDD diffusion layer 15 is formed in an upper portion of first semiconductor pillar 6, and stacked diffusion layer 17 formed of a stacked silicon layer is provided on the upper surface of LDD diffusion layer 15. LDD diffusion layer 15 and stacked diffusion layer 17 form upper diffusion layer 17c, which forms the other one of the source/drain diffusion layers of the vertical transistor.

First gate electrode 13 is disposed so that it covers circumferential side surfaces of first combined pillar 8. As for first semiconductor pillar 6, first gate electrode 13 is disposed via gate insulator 12 so that first gate electrode 13 covers the following three side surfaces of first semiconductor pillar 6: side surface 6c, which is one of the side surfaces facing each other in direction X; and two side surfaces 6b and 6d facing each other in direction Y. First gate electrode 13 and stacked diffusion layer 17 are insulated from each other by sidewall insulating film 16. First combined pillar 8, and gate insulator 12 and first gate electrode 13, which cover side surfaces 6b, 6c, and 6d of first semiconductor pillar 6, form first vertical transistor Tr1.

First interlayer insulating film 14 is formed around combined pillar 8, and second interlayer insulating film 19 is formed so that it covers the entire surface of the resultant structure. Contact plug (second conductive material) 21, which feeds electric power to lower diffusion layer 11, is electrically connected to lower diffusion layer 11 through second interlayer insulating film 19, first interlayer insulating film 14, and lower oxide film 10. Further, contact plug (first conductive material) 22, which feeds electric power to upper diffusion layer 17c, is electrically connected to upper diffusion layer 17c through second interlayer insulating film 19. Moreover, contact plug 23, which feeds electric power to first gate electrode 13, is electrically connected to first gate electrode 13 through second interlayer insulating film 19 and part of first interlayer insulating film 14. Wiring lines 24 are formed on interlayer insulating film 19 so that they are electrically connected to contact plugs 21 to 23.

As described above, according to the exemplary embodiment, providing first combined pillar 8, which is a combination of first semiconductor pillar 6, which forms vertical transistor Tr1, and first insulator pillar 7, allows part of first gate electrode 13 formed on circumferential side surfaces of first combined pillar 8 to be disposed on isolation region 2. As a result, contact plug 23, which feeds electric power to first gate electrode 13, can be provided on isolation region 2. Therefore, even if the plan-view position where contact plug 23 is disposed is shifted from the position of first gate electrode 13 and hence contact plug 23 is formed to the same depth as that of contact plug 21, the insulator that forms isolation region 2 is present below contact plug 23 and prevents contact plug 23 and silicon substrate 1 (lower diffusion layer) from forming a short circuit. As a result, it is possible to provide an improved semiconductor device with a vertical transistor having stable transistor characteristics and a method for manufacturing the semiconductor device.

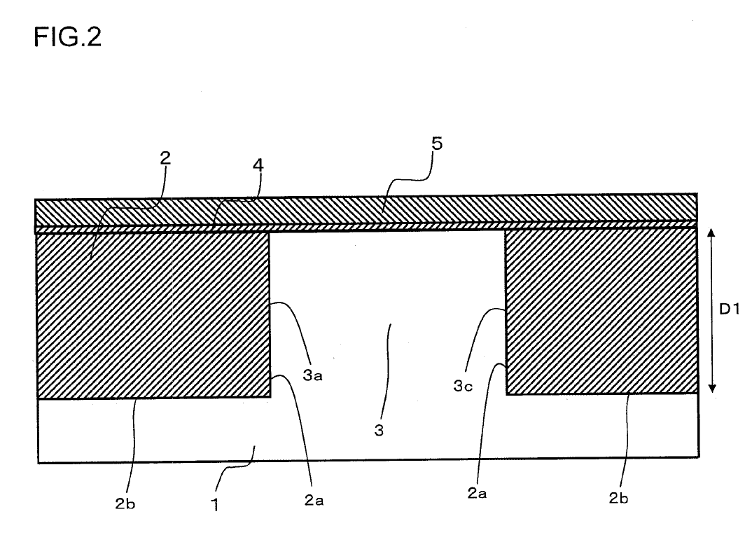

A method for manufacturing the semiconductor device shown in FIGS. 1A to 1D will be described below with reference to the plan view of FIG. 1A and FIGS. 2 to 10. FIGS. 2 to 10 are cross-sectional views taken along line B-B in FIG. 1A.

First, trench 2b is formed in the upper surface of p-type single-crystal silicon substrate (hereinafter described as “substrate”) 1 and filled with an insulator formed of a silicon oxide film in a known STI process, as shown in FIG. 2. Isolation region 2 having depth D1 of 250 nm is thus formed. Active region 3 formed of substrate 1 and surrounded with sidewall 2a of trench 2b, which forms isolation region 2, is formed at the same time. Active region 3 has, but not necessarily, a rectangular plan-view shape including first side surface 3a and third side surface 3c facing each other in direction X and second side surface 3b and fourth side surface 3d located between first side surface 3a and third side surface 3c and facing each other in direction Y (FIG. 2 does not show second side surface 3b or fourth side surface 3d). Pad oxide film 4 formed of a silicon oxide film having a thickness of 5 nm and silicon nitride film 5 having a thickness of 100 nm are then formed on the entire surface of substrate 1.

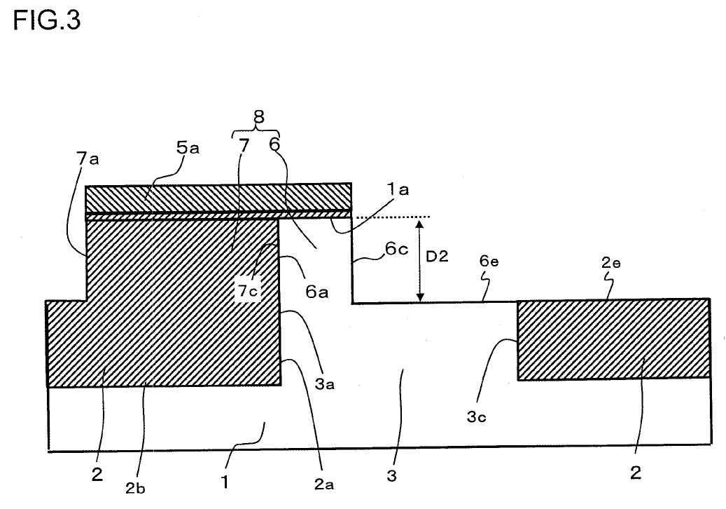

Silicon nitride film 5 and silicon oxide film 4 are etched by using known photolithography and dry etching technologies to form mask nitride film 5a, as shown in FIG. 3. Mask nitride film 5a is positioned so that it extends along active region 3 and isolation region 2 and covers one side surface of active region 3. In the exemplary embodiment, mask nitride film 5a is positioned so that it covers first side surface 3a, but not necessarily, it may alternatively be so positioned that it covers any of the other side surfaces of active region 3. Mask nitride film 5a is then used as a mask to etch substrate 1 that forms active region 3 and the silicon oxide film that forms isolation region 2 simultaneously to form first semiconductor pillar 6 located in active region 3 and first insulator pillar 7 located in the isolation region.

First semiconductor pillar 6 has a rectangular plan-view shape including first side surface 6a and third side surface 6c facing each other in direction X and second side surface 6b and fourth side surface 6d located between first side surface 6a and third side surface 6c and facing each other in direction Y (FIG. 2 does not show second side surface 6b or fourth side surface 6d). On the other hand, first insulator pillar 7 has a rectangular plan-view shape including first side surface 7a and third side surface 7c facing each other in direction X and second side surface 7b and fourth side surface 7d located between first side surface 7a and third surface 7c and facing each other in direction Y (FIG. 2 does not show second side surface 7b or fourth side surface 7d). First semiconductor pillar 6 and first insulator pillar 7, whose first side surface 6a and third side surface 7c are in contact with each other at first side surface 3a of active region 3, form integrated first combined pillar 8. That is, first insulator pillar 7 is in contact with first semiconductor pillar 6 with sidewall 2a of trench 2b therebetween.

Width W3 of first semiconductor pillar 6 in direction Y is formed to be narrower than width W1 of active region 3 in direction Y. That is, second side surface 6b and fourth side surface 6d facing each other in direction Y of first semiconductor pillar 6 are located in the active region. Further, width W2 of first insulator pillar 7 in direction Y may or may not be equal to width W3 of first semiconductor pillar 6 in direction Y. In the exemplary embodiment, the height of first semiconductor pillar 6, that is, depth D2 thereof from substrate surface 1a to bottom surface 6e of first semiconductor pillar 6 is set, for example, at 150 nm. In the exemplary embodiment, substrate 1 that forms active region 3 and the silicon oxide film that forms isolation region 2 are etched simultaneously by using fluorine-containing plasma, but they may alternatively be etched separately. That is, the silicon oxide film in isolation region 2 may first be etched under the condition that a silicon oxide film is etched, and the substrate silicon in active region 3 may then be etched under the condition that silicon is etched. In both cases, the etching is performed so that bottom surface 6e of first semiconductor pillar 6 is flush with upper surface 2e of etched isolation region 2.

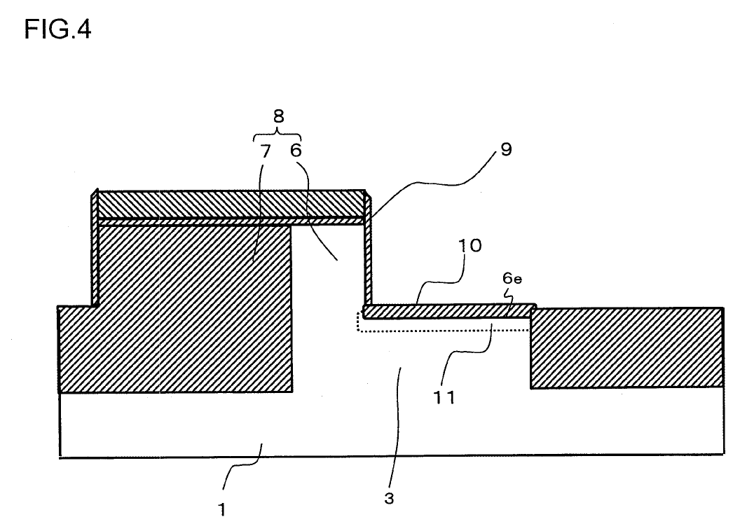

A silicon nitride film is then formed on the entire surface of the resultant structure, for example, to a thickness of 10 nm, as shown in FIG. 4. The silicon nitride film is formed by using dichlorosilane (SiH₂Cl₂) and ammonia (NH₃) as raw material gases in an LPCVD process at a temperature of 750° C. under a pressure of 60 Pa. A silicon nitride film formed in an LPCVD process excels in step coverage characteristic, whereby the silicon nitride film on first semiconductor pillar 6 can be uniformly formed on the side surfaces thereof as well. The entire silicon nitride film is then etched back in a dry etching process using fluorine-containing plasma to form first sidewall nitride film 9 on all the side surfaces of first combined pillar 8, which is formed of first semiconductor pillar 6 and first insulator pillar 7. Lower insulating film 10 formed of a silicon oxide film having, for example, a thickness of 20 nm is then selectively formed on exposed substrate surface 6e of active region 3 in a thermal oxidation process.

An n-type impurity, such as phosphorus and arsenic, is then ion-implanted into the entire surface of the resultant structure, to form lower diffusion layer 11, which is in contact with the bottom surface of lower insulating film 10, in the surface of substrate 1 below lower insulating film 10 formed in active region 3. After the ion implantation, the impurity is activated in a heat treatment, for example, at 1000° C. for 10 seconds to form an n-type semiconductor region. Lower diffusion layer 11 forms one of the source and drain of the vertical transistor including semiconductor pillar 6 as a channel. The impurity concentration in lower diffusion layer 11 is set at a value ranging from 1×10²⁰ to 1×10²¹ atoms/cm³. In the implantation process, since the sidewall of semiconductor pillar 6 is coated with first sidewall nitride film 9, phosphorus or arsenic can be prevented from be implanted into the pillar.

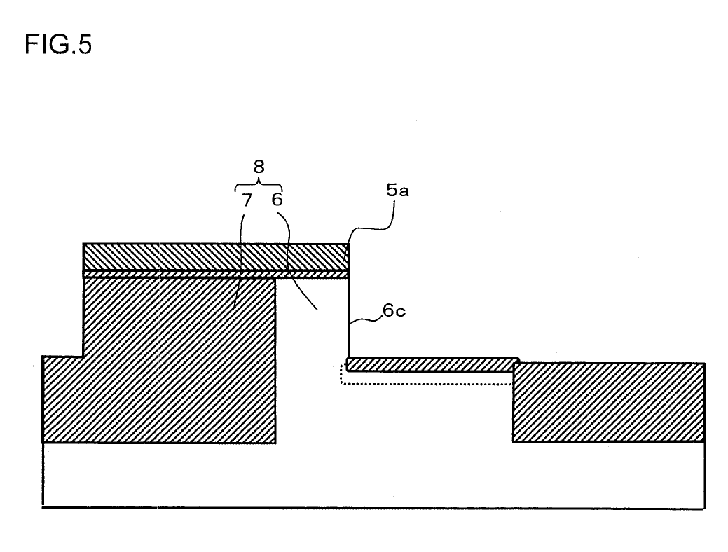

First combined pillar 8, which is formed of first semiconductor pillar 6 and first insulator pillar 7, is then immersed in a phosphoric acid liquid heated, for example, to 150° C. so that first sidewall nitride film 9 formed on the side surfaces of first combined pillar 8 is removed, as shown in FIG. 5. In this process, mask nitride film 5a is also etched from the upper surface thereof by about 10 nm, but the remaining mask nitride film has a thickness of about 90 nm, which is thick enough, because mask nitride film 5a is originally as thick as 100 nm. The substrate silicon is therefore exposed across second side surface 6b, third side surface 6c, and fourth side surface 6d, which form first semiconductor pillar 6 (FIG. 5 does not show second side surface 6b or fourth side surface 6d).

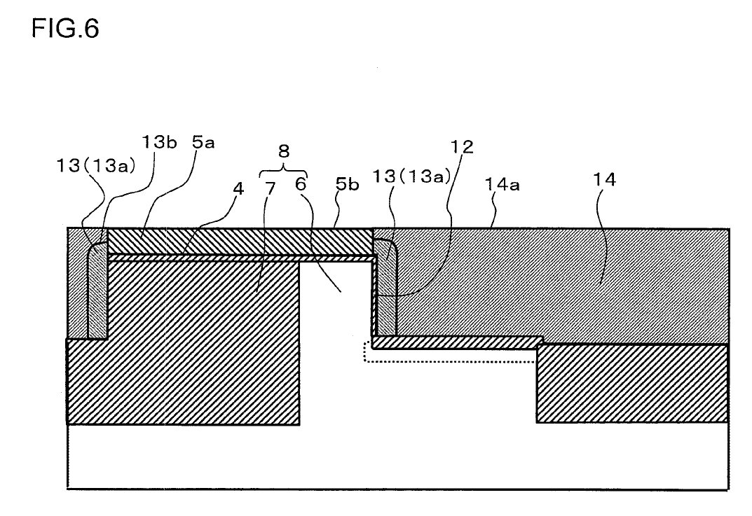

Gate insulator 12 formed of a silicon oxide film is then formed, for example, to a thickness of 5 nm on the side surfaces of first semiconductor pillar 6 in a thermal oxidation process, as shown in FIG. 6. The gate insulator is thus formed on second side surface 6b, third side surface 6c, and fourth side surface 6d of first semiconductor pillar 6, where the substrate silicon is exposed. An amorphous silicon film containing phosphorus at a concentration of 5×10²⁰ atoms/com³ is then formed on the entire surface of the resultant structure in an LPCVD process. The film thickness of the amorphous silicon film is set at a value ranging from 5 to 20 nm. The amorphous silicon film is formed by using monosilane (SiH₄) or disilane (Si₂H₆) and phosphine (PH₃) as raw material gases at a temperature of 530° C. under a pressure of 60 Pa. The entire amorphous silicon film is then etched back in a dry etching process using plasma containing bromine, chlorine, and oxygen so that the amorphous silicon film containing phosphorus is left as a sidewall on all the side surfaces of first combined pillar 8 including the surface of gate insulator 12. The etch back process is carried out so that upper end surface 13b of sidewall amorphous silicon film 13a is in contact with the sidewall of mask nitride film 5a at a level between upper surface 5b of mask nitride film 5a and the upper surface of pad oxide film 4. If upper end surface 13b of amorphous silicon film 13a is located below the upper surface of pad oxide film 4, gate insulator 12, which is located at the shoulder of first semiconductor pillar 6, is exposed during the etch back process and will be etched away in the following washing step, which is not preferable.

Amorphous silicon film 13a is then converted into a polycrystalline silicon film in a heat treatment performed, for example, at 1000° C. for 10 seconds, and at the same time, the impurity phosphorus contained in the amorphous silicon film is activated. The polycrystalline silicon film is thus converted into an n-type conductor and forms first gate electrode 13. First interlayer insulating film 14 is then formed in a spin coating process so that it covers mask nitride film 5a, and then first interlayer insulating film 14 is planarized by using a CMP technology so that upper surface 5b of mask nitride film 5a is exposed. Mask nitride film 5a functions as a stopper film in the CMP process. As a result, upper surface 5b of mask nitride film 5a becomes flush with upper surface 14a of first interlayer insulating film 14.

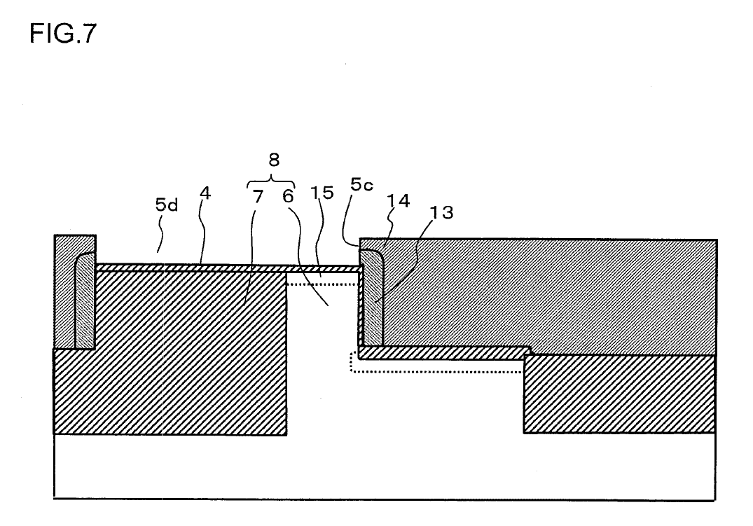

The resultant structure is then immersed in a phosphoric acid liquid heated, for example, to 150° C. so that mask nitride film 5a is removed, as shown in FIG. 7. Opening 5d, whose plan-view shape conforms to the upper surface of combined pillar 8, is thus formed. Opening 5d includes sidewall 5c, which is formed of part of first interlayer insulating film 14 and part of first gate electrode 13, and a bottom surface formed of pad oxide film 4. LDD diffusion layer 15 is then formed in the surface of an upper portion of first semiconductor pillar 6 by ion-implanting phosphorus into the entire surface of the resultant structure. The impurity concentration of the LDD diffusion layer 15 is set at a value ranging from 1×10¹⁸ to 1×10¹⁹ atoms/cm³.

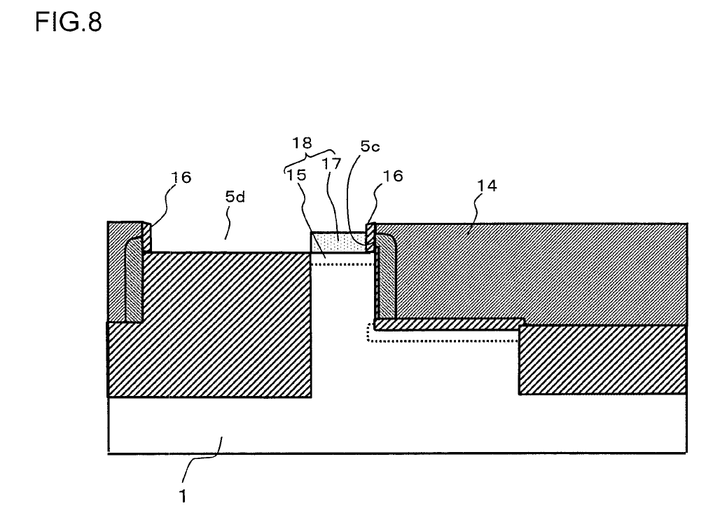

Pad oxide film 4 is then removed by using a hydrofluoric-acid-containing solution so that the upper surface of LDD diffusion layer 15 is exposed, as shown in FIG. 8. A silicon nitride film is then formed, for example, to a thickness of 10 nm on the entire surface of the resultant structure in the LPCVD process described above. The entire surface of the resultant structure is then etched back in a dry etching process to form second sidewall nitride film 16 on sidewall 5c. Stacked diffusion layer 17 formed of a single-crystal stacked silicon layer is then formed on the exposed upper surface of LDD diffusion layer 15 in a selective epitaxial growth process. Since a selective epitaxial growth proceeds from a seed, which is in this case crystal grains exposed at the surface of the single-crystal silicon substrate that forms LDD diffusion layer 15, the resultant grown silicon film always has a single-crystal state. To grow single-crystal silicon in a selective epitaxial growth process, dichlorosilane (SiH₂Cl₂) and hydrogen chloride (HCl) may be used as raw material gases in a hydrogen atmosphere under a pressure below the atmospheric pressure at a temperature ranging from 750 to 900° C. Alternatively, n-type single-crystal silicon containing phosphorus can be formed by introducing phosphine (PH₃) into the raw material gases. The resultant silicon formed in the method described above is conductive because a single-crystal state is achieved in the film formation stage. No heat treatment for activation in the following step is therefore necessary.

On the other hand, stacked diffusion layer 17 may alternatively be made of polycrystalline silicon. To this end, part of the conditions described above only needs to be changed. That is, the hydrogen atmosphere is replaced with an atmosphere containing hydrogen and nitrogen. The introduced nitrogen terminates each crystal grain exposed at the surface of single-crystal silicon substrate 1, which forms LDD diffusion layer 15, and hence prevents each crystal grain from functioning as a seed. As a result, epitaxial growth does not occur but silicon having a polycrystalline state is formed. The polycrystalline silicon can also be selectively formed only on the LDD diffusion layer. The surface of the grown film includes irregularities because a variety of crystal planes appear at the upper surface of the film formed in a single-crystal silicon growth process. On the other hand, the irregularities of a silicon film having a polycrystalline state are very small, allowing formation of stacked silicon film 17 including a flatter surface. In this case as well, introducing phosphine (PH₃) into the raw material gases allows formation of n-type polycrystalline silicon containing phosphorus.

Stacked diffusion layer 17 is formed to a height lower than the upper surface of first interlayer insulating film 14, that is, to a thickness smaller than the depth of opening 5d. Stacked diffusion layer 17 can alternatively be formed by first forming a non-doped silicon film with no impurity introduced during the film formation and then introducing phosphorus or arsenic into the non-doped silicon film in an ion implantation process. In this case, however, a heat treatment for activating the impurity needs to be carried out after the ion implantation. The impurity concentration of stacked diffusion layer 17 is set at a value ranging from 1×10²⁰ to 1×10²¹ atoms/cm³. LDD diffusion layer 15 and stacked silicon film 17 function as upper diffusion layer 18.

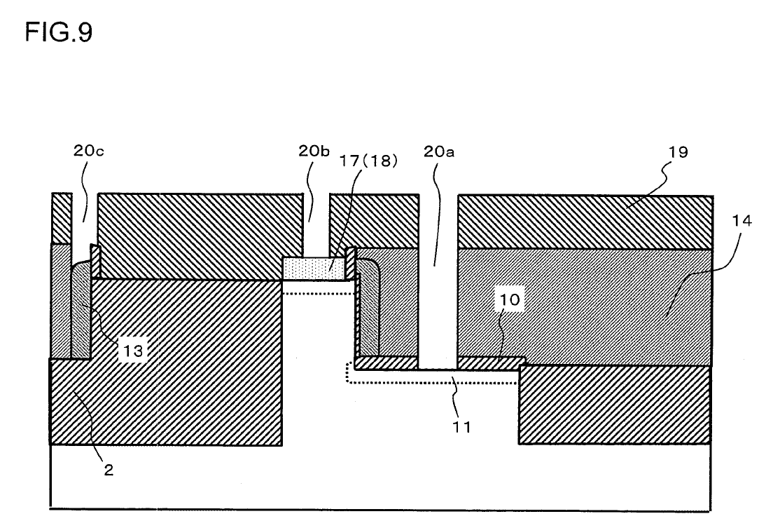

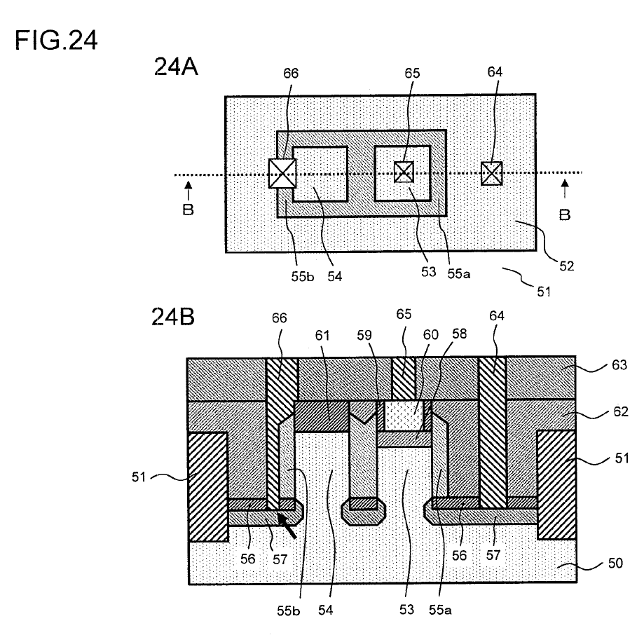

A silicon oxide film is then formed on the entire surface of the resultant structure in a CVD process or a spin coating process, and the surface of the silicon oxide film is planarized in a CMP process to form second interlayer insulating film 19 on first interlayer insulating film 14, for example, to a thickness of 80 nm, as shown in FIG. 9. First contact hole 20a, second contact hole 20b, and third contact hole 20c are simultaneously formed in lithography and dry etching processes. First contact hole 20a is formed through second interlayer insulating film 19, first interlayer insulating film 14, and lower insulating film 10, so that the upper surface of lower diffusion layer 11 is exposed at the bottom of first contact hole 20a. Second contact hole 20b is formed through second interlayer insulating film 19, so that stacked silicon film 17, which forms upper diffusion layer 18, is exposed at the bottom of second contact hole 20b. Third contact hole 20c is formed through second interlayer insulating film 19 and part of first interlayer insulating film 14, so that gate electrode 13 is exposed at the bottom of third contact hole 20c. If third contact hole 20c is formed as in the related art shown in FIGS. 24A and 24B, in which a contact hole for feeding electric power to the gate electrode is formed above the end of dummy pillar 54 formed adjacent to pillar 53 in single active region 52, lower diffusion layer 57 may be exposed due to pattern misalignment, causing a problem of a short circuit between gate electrode 55b and lower diffusion layer 57 when contact plug 66 is formed.

In contrast, in the exemplary embodiment, the contact hole for feeding electric power to the gate electrode is formed in isolation region 2 formed of a thick insulator. Therefore, first gate electrode 13 and lower diffusion layer 11 does not form no short circuit when the contact plug is formed. As shown in the plan view of FIG. 1A, third contact hole 20c is formed in a portion that overlaps with one side surface 7a of first insulator pillar 7, but third contact hole 20c is not necessarily formed in the position described above and may alternatively be formed in a portion that overlaps with one of side surfaces 7b and 7d facing each other in direction Y. Further, first contact hole 20a is formed at the center of active region 3 in direction Y but does not necessarily formed in the position described above and as long as the first contact hole 20a is not in contact with first gate electrode 13, first contact hole 20 may be formed in any portion in active region 3.

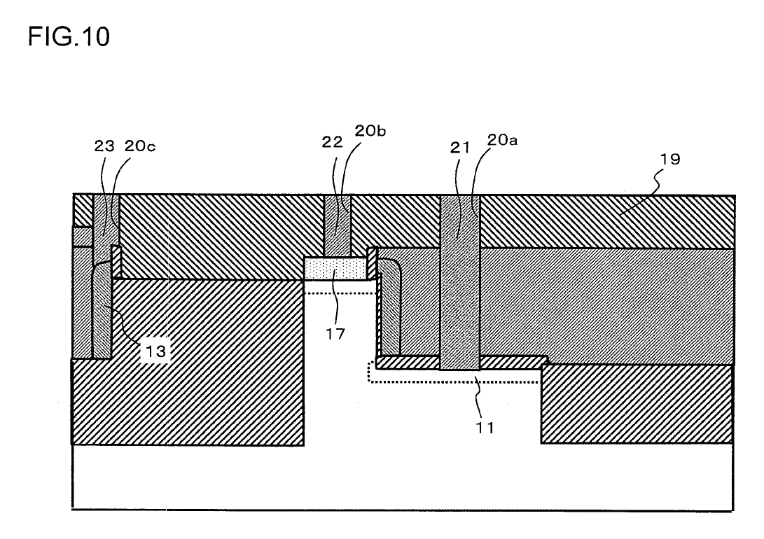

A cobalt film is then formed on the entire surface of the resultant structure in a sputtering process, and the resultant structure is heat treated at a temperature ranging from 500 to 800° C., as shown in FIG. 10. The heat treatment causes the cobalt film formed on lower diffusion layer 11 exposed at the bottom of first contact hole 20a, the cobalt film formed on stacked silicon film 17 exposed at the bottom of second contact hole 20b, and the cobalt film formed on gate electrode 13 exposed at the bottom of third contact hole 20c to react with the silicon that forms the exposed surfaces. As a result, the cobalt films are converted into cobalt silicide films. The cobalt silicide films contribute to reduction in contact resistance of the contact plugs. Unreacted cobalt films formed on the sidewall of each of the contact holes and the upper surface of second interlayer insulating film 19 are then removed by using a sulfuric acid liquid.

A barrier layer made of titanium (Ti) and a titanium nitride (TiN) is then formed in a CVD process by sequentially depositing these two materials in the contact holes to a thickness that does not fill the contact holes. Contact between the cobalt silicide films and the TiN causes an increases in resistance, but low resistance can be maintained by interposing the Ti between the cobalt silicide films and the TiN. Tungsten (W) is then deposited on the entire surface of the resultant structure to a thickness that fills the contact holes in a CVD process. The W/TiN/Ti layered film formed on second interlayer insulating film 19 is then removed in a CMP process. Contact plug (second conductive material) 21, contact plug (first conductive material) 22, and contact plug 23, each of which includes the cobalt silicide film at the bottom and is filled with the W/TiN/Ti layered film, are thus formed. Contact plug 21 functions as a component that feeds electric power to lower diffusion layer 11. Contact plug 22 functions as a component that feeds electric power to upper diffusion layer 17. Contact plug 23 functions as a component that feeds electric power to first gate electrode 13 of the vertical transistor. After wiring lines 24 to be connected to the contact plugs are then formed, vertical transistor Tr1, which is formed of first combined pillar 8 formed of first semiconductor pillar 6 and first insulator pillar 7, is formed, as shown in FIG. 1B. As described above, according to the method for manufacturing a semiconductor device of the exemplary embodiment, first semiconductor pillar 6, which forms vertical transistor Tr1, is combined with first insulator pillar 7 to form first combined pillar 8. Part of first gate electrode 13 formed on circumferential side surfaces of first combined pillar 8 can therefore be formed in isolation region 2. As a result, contact plug 23, which feeds electric power to first gate electrode 13, can be formed above isolation region 2. It is possible to prevent contact plug 23 and silicon substrate 1 (lower diffusion layer 11) from forming a short circuit even if the plan-view position where contact plug 23 is formed is shifted from the position of first gate electrode 13 and hence contact plug 23 is formed to the same depth of that of contact plug 21, because the insulator that forms isolation region 2 is present below contact plug 23.

In some cases, the first semiconductor pillar formed in the active region is separated from the first insulator pillar formed in the isolation region so that the pillars are adjacent to but independent from each other, and the gate electrode that surrounds the first semiconductor pillar and the gate electrode that surrounds the first insulator pillar are connected to each other by filling the space between the first semiconductor pillar and the first insulator pillar with a common gate electrode. In this case, however, the independent insulator pillar allows all the circumferential side surfaces thereof to be etched in a pre-washing step or any other washing step before the formation of the gate insulator, and the entire insulator pillar becomes thinner, resulting in a problem of an increase in the distance between the first semiconductor pillar and the first insulator pillar and hence no connection between the gate electrodes.

In contrast, according to the method for manufacturing a semiconductor device of the exemplary embodiment, in which first semiconductor pillar 6 and first insulator pillar 7 are combined with each other, the surface where the pillars are combined with each other is not be exposed to washing or the two pillars are not be separated. Therefore, it is possible to avoid the problem described above.

### Second Exemplary Embodiment

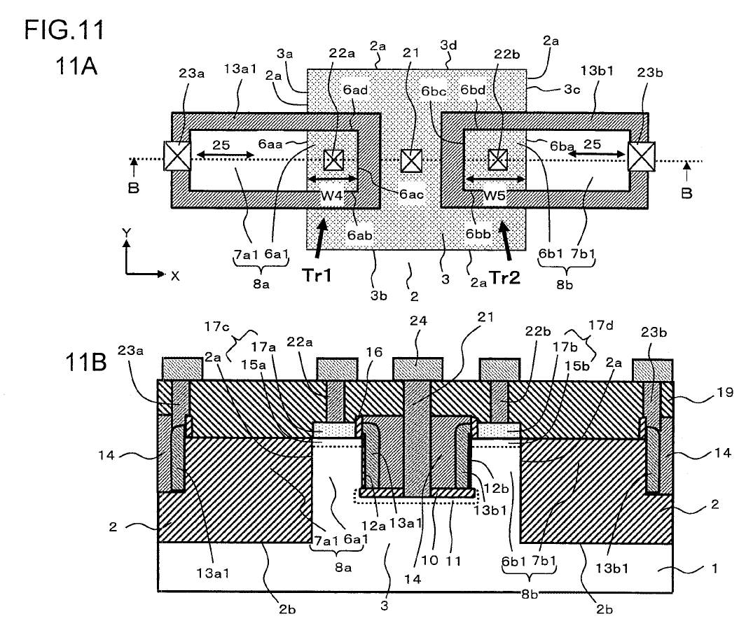

FIGS. 11A and 11B show the configuration of a second exemplary embodiment. In the configuration of the semiconductor device shown in FIGS. 1A to 1D, vertical transistor Tr1 is formed of single semiconductor pillar 6 in single active region 3, whereas in the exemplary embodiment, a description will be made of the configuration of vertical transistors formed of a pair of semiconductor pillars 6a1 and 6b1 in contact with side surfaces facing each other in single active region 3. The pair of vertical transistors in the exemplary embodiment are connected serially or in parallel to each other and function as a single vertical transistor. FIG. 11A is a plan view, and FIG. 11B is a cross-sectional view taken along line B-B in FIG. 11A.

Isolation region 2 is formed by filling trench 2b with an insulating material, as shown in FIGS. 11A and 11B. Active region 3 surrounded with isolation region 2 is provided in the surface of silicon substrate 1. That is, active region 3 is surrounded with sidewall 2a of trench 2b. Active region 3 has a rectangular shape including side surfaces 3a and 3c facing each other in direction X and side surfaces 3b and 3d facing each other in direction Y, as in the first exemplary embodiment. First semiconductor pillar 6a1 is disposed in silicon substrate 1 in active region 3 and in contact with side surface 3a of active region 3. Second semiconductor pillar 6b1 is disposed so that it is in contact with side surface 3c, which faces side surface 3a. First semiconductor pillar 6a1 has a rectangular shape including side surface 6aa (which coincides with first side surface of first insulator pillar 7a1) and side surface 6ac facing each other in direction X and side surfaces 6ab and 6ad facing each other in direction Y. On the other hand, second semiconductor pillar 6b1 has a rectangular shape including side surface 6ba (which coincides with second side surface of second insulator pillar 7b1) and side surface 6bc facing each other in direction X and side surfaces 6bb and 6bd facing each other in direction Y. First semiconductor pillar 6a1 and second semiconductor pillar 6b1 form a semiconductor pillar pair.

First insulator pillar 7a1 formed of the insulator that forms isolation region 2 is disposed in isolation region 2 that is in contact with side surface 3a of active region 3. Second insulator pillar 7b1 is disposed in isolation region 2 that is in contact with side surface 3c, which faces side surface 3a. First insulator pillar 7a1 is in contact with side surface 6aa of first semiconductor pillar 6a1 at side surface 3a of the active region. That is, first insulator pillar 7a1 is in contact with first semiconductor pillar 6a1 with sidewall 2a of trench 2b interposed therebetween, to obtain first combined pillar 8a, which is a combination of first semiconductor pillar 6a1 and first insulator pillar 7a1, extends in active region 3 and isolation region 2. On the other hand, second insulator pillar 7b1 is in contact with side surface 6ba of second semiconductor pillar 6b1 at side surface 3c of the active region. That is, second insulator pillar 7b1 is in contact with second semiconductor pillar 6b1 with sidewall 2a of trench 2b interposed therebetween, to obtain second combined pillar 8b, which is a combination of second semiconductor pillar 6b1 and second insulator pillar 7b1, extends in active region 3 and isolation region 2.

First combined pillar 8a and second combined pillar 8b form a combined pillar pair. Each of first combined pillar 8a and second combined pillar 8b extends in direction X. First combined pillar 8a and second combined pillar 8b need to extend in the same direction, but they do not need to be located in the same position in direction Y. In FIG. 11A, the centers of first combined pillar 8a and second combined pillar 8b in direction Y are located in the same position on line B-B, but they are not necessarily located as described above and may be shifted from each other in direction Y. Since the basic configuration of each of combined pillars 8a and 8b is the same as that in the first exemplary embodiment, no redundant description of the basic configuration will be made.

Lower oxide film 10 is formed on the upper surface of active region 3 except first semiconductor pillar 6a1 and second semiconductor pillar 6b1. Further, first and second lower diffusion layers 11, which form one of source/drain diffusion layers of each of the vertical transistors, are formed in the surface of silicon substrate 1 located below lower oxide film 10. First and second lower diffusion layers 11 are lower diffusion layers common to two vertical transistors Tr1 and Tr2 facing each other.

First LDD diffusion layer 15a is formed in an upper portion of first semiconductor pillar 6a1, and stacked diffusion layer 17a formed of a stacked silicon layer is provided on the upper surface of LDD diffusion layer 15a. Second LDD diffusion layer 15b is formed in an upper portion of second semiconductor pillar 6b1, and stacked diffusion layer 17b formed of a stacked silicon layer is provided on the upper surface of LDD diffusion layer 15b. LDD diffusion layer 15a and stacked diffusion layer 17a form first upper diffusion layer 17c, which forms the other one of the source/drain diffusion layers of the corresponding vertical transistor. In addition, LDD diffusion layer 15b and stacked diffusion layer 17b form second upper diffusion layer 17d, which forms the other one of the source/drain diffusion layers of the corresponding vertical transistor.

First gate electrode 13a1 is disposed so that it covers circumferential side surfaces of first combined pillar 8a. First gate insulator 12a is provided between first gate electrode 13a1 and first semiconductor pillar 6a. Second gate electrode 13b1 is disposed so that it covers circumferential side surfaces of second combined pillar 8b. Second gate insulator 12b is provided between second gate electrode 13b1 and second semiconductor pillar 6b.

First vertical transistor Tr1 is formed of first combined pillar 8a, and first gate insulator 12a and first gate electrode 13a1, which cover side surfaces 6ab, 6ac, and 6ad of first semiconductor pillar 6a1. Second vertical transistor Tr2 is formed of second combined pillar 8b, and second gate insulator 12b and second gate electrode 13b1, which cover side surfaces 6bb, 6bc, and 6bd of second semiconductor pillar 6b1. First vertical transistor Tr1 and second vertical transistor Tr2 form a transistor pair. Lower diffusion layer 11 is shared by first vertical transistor Tr1 and second vertical transistor Tr2.

First interlayer insulating film 14 is formed around first combined pillar 8a and second combined pillar 8b, and second interlayer insulating film 19 is further formed so that it covers the entire surface of the resultant structure. Contact plug 21, which feeds electric power to first and second lower diffusion layers 11, is formed through second interlayer insulating film 19, first interlayer insulating film 14, and lower oxide film 10. Further, contact plugs 22a and 22b, which feed electric power to first upper diffusion layer 17c and second upper diffusion layer 17d respectively, are formed through second interlayer insulating film 19. Moreover, there are formed contact plug 23a, which feeds electric power to first gate electrode 13a1, and contact plug 23b, which feeds electric power to second gate electrode 13b1, through second interlayer insulating film 19 and part of first interlayer insulating film 14. Wiring lines 24 are formed on interlayer insulating film 19 so that they are connected to contact plugs 21, 22a, 22b, 23a, and 23b.

As described above, according to the exemplary embodiment, first vertical transistor Tr1 and second vertical transistor Tr2 include first and second insulator pillars 7a1, 7b1 and contact plugs 23a and 23b, which feed electric power to the gate electrodes, are provided in portions that overlap with first and second gate electrodes 13a1, 13b1 located on circumferential side surfaces of first and second insulator pillars 7a1, 7b1 formed in isolation region 2, as in the first exemplary embodiment. It is possible to prevent contact plugs 23a, 23b, which feed electric power to the gate electrodes, and silicon substrate 1 (first and second lower diffusion layer 11) from forming short circuit.

Further, according to the exemplary embodiment, first semiconductor pillar 6a1, which forms first vertical transistor Tr1, is provided so that it is in contact with side surface 3a of active region 3, and second semiconductor pillar 6b1, which forms second vertical transistor Tr2, is provided in the same active region 3 so that it is in contact with side surface 3c, which faces side surface 3a. The sum of width W4 of first semiconductor pillar 6a in direction X (direction 25 in which combined pillar extends) and width W5 of second semiconductor pillar 6b in direction X can therefore be always maintained at a fixed value even if a pattern shift occurs in direction X relative to active region 3 when combined pillars 8a and 8b are formed. For example, assume that each of W4 and W5 is 30 nm in an ideal state in which no pattern shift occurs. In this case, the total width is 60 nm. Further assuming that a pattern shift occurs leftward in direction X by 5 nm when combined pillars 8a and 8b are formed, W4 becomes 25 nm and W5 becomes 35 nm. On the other hand, the total width remains unchanged at 60 nm, which is equal to the total width provided when no pattern shift occurs. Therefore, first vertical transistor Tr1 and second vertical transistor Tr2 are connected serially or in parallel to each other and used as a single vertical transistor, thereby obtaining the single vertical transistor that always has a fixed total width of the semiconductor pillars.

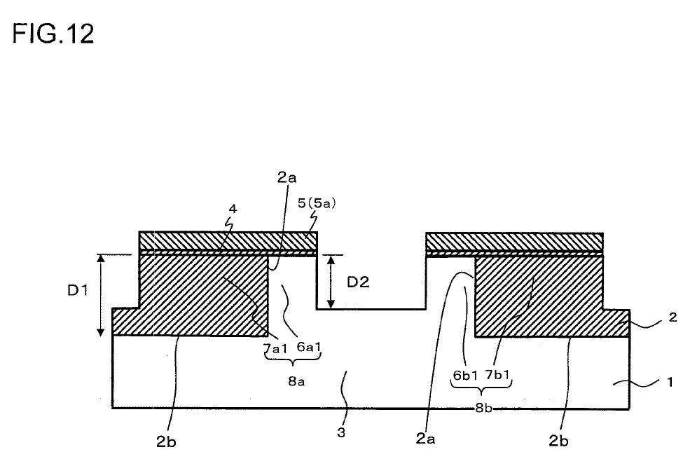

A method for manufacturing the semiconductor device shown in FIGS. 11A and 11B will be described below with reference to the plan view of FIG. 11A and FIGS. 12 to 16. FIGS. 12 to 16 are cross-sectional views taken along line B-B in FIG. 11A. Since the manufacturing method according to the exemplary embodiment includes the same steps as those of the manufacturing method according to the first exemplary embodiment except the step of disposing two combined pillars facing each other, no redundant description of the same steps will be made.

First, trench 2b including sidewall 2a is formed in the upper surface of p-type single-crystal silicon substrate (hereinafter referred to as “substrate”) 1, and isolation region 2 having depth D1 of 250 nm measured from the surface of substrate 1 is formed by filling trench 2b with an insulator, as shown in FIG. 12. Active region 3 formed of substrate 1 surrounded with sidewall 2a of trench 2b is thus formed. Pad oxide film 4 and silicon nitride film 5 having a thickness of 100 nm are then formed on the entire surface of substrate 1. Silicon nitride film 5 and silicon oxide film 4 are then etched by using known photolithography and dry etching technologies to form mask nitride film 5a. Mask nitride film 5a is formed in two portions each of which extends along active region 3 and isolation region 2 and overlaps corresponding one of side surfaces of active region 3 facing each other. Mask nitride films 5a are then used as a mask to etch substrate 1 that forms active region 3 and the silicon oxide film that forms isolation region 2, thereby forming two combined pillars 8a and 8b. First combined pillar 8a is a combination of first semiconductor pillar 6a1 and first insulator pillar 7a1, and second combined pillar 8b is a combination of second semiconductor pillar 6b1 and second insulator pillar 7b1. Each of combined pillars 8a and 8b has depth D2 of 150 nm measured from the surface of substrate 1.

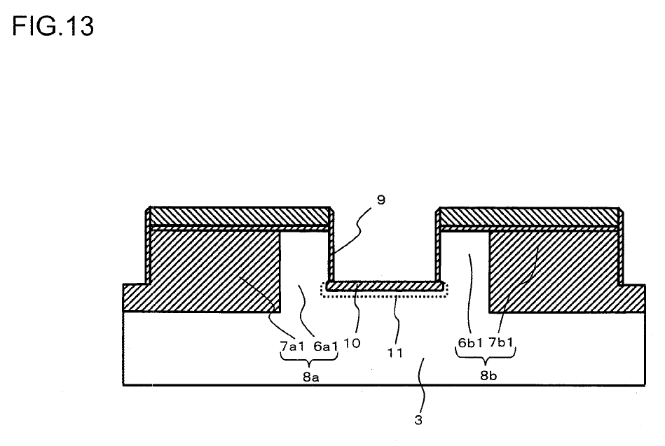

A silicon nitride film is then formed on the entire surface of the resultant structure, for example, to a thickness of 10 nm, as shown in FIG. 13. The entire silicon nitride film is then etched back to form first sidewall nitride film 9 on all the side surfaces of first combined pillar 8a and second combined pillar 8b. Lower insulating film 10 having a thickness of, for example, 20 nm is next selectively formed in the substrate surface exposed in active region 3 (corresponding to bottom position of each pillar) in a thermal oxidation process. An n-type impurity, such as phosphorus and arsenic, is then ion-implanted into the entire surface of the resultant structure to form first and second lower diffusion layers 11, which are in contact with the bottom surface of lower insulating film 10, in the surface of substrate 1 below lower insulating film 10 formed in active region 3.

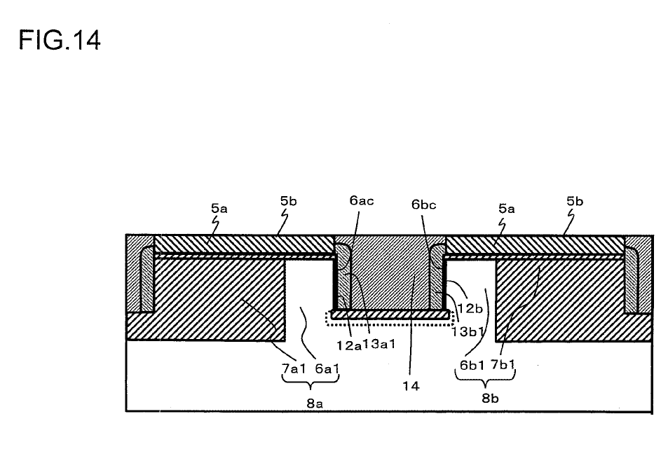

First sidewall nitride film 9 formed on the side surfaces of first and second combined pillars 8a, 8b is then removed so that substrate silicon of side surfaces 6ab, 6ac, and 6ad of first semiconductor pillar 6a1 and side surfaces 6bb, 6bc, and 6bd of second semiconductor pillar 6b1 is exposed, as shown in FIG. 14 (FIG. 14 does not show side surface 6ab, 6ad, 6bb, or 6bd). First and second gate insulators 12a, 12b are then formed on the side surfaces of semiconductor pillars 6a1 and 6b1 where substrate silicon is exposed, respectively. An impurity-containing amorphous silicon film is then formed on the entire surface of the resultant structure. The entire surface of the resultant structure is then etched back so that the impurity-containing amorphous silicon film is left as a sidewall on all the side surfaces of first and second combined pillars 8a, 8b including the surfaces of first and second gate insulators 12a, 12b. The amorphous silicon films are then converted into polycrystalline silicon films in a heat treatment performed, for example, at 1000° C. for 10 seconds, and at the same time, the impurity phosphorus contained in the amorphous silicon films is activated. The polycrystalline silicon films are thus converted into an n-type conductor, thereby forming first gate electrode 13a1 and second gate electrode 13b1. First interlayer insulating film 14 is then formed in a spin coating process so that it covers mask nitride film 5a, and then first interlayer insulating film 14 is planarized by using a CMP technology so that upper surface 5b of mask nitride film 5a is exposed.

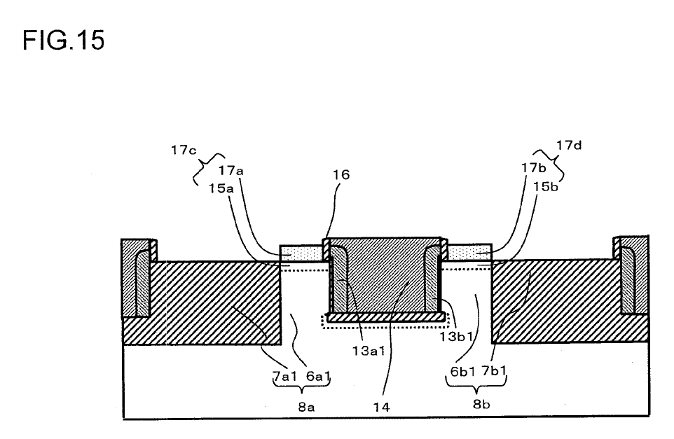

The resultant structure is then immersed in a phosphoric acid liquid so that mask nitride film 5a is selectively removed, as shown in FIG. 15. Openings whose plan-view shapes conform to the upper surfaces of combined pillars 8a and 8b are thus formed. Each of the openings includes a sidewall formed of part of first interlayer insulating film 14 and part of the corresponding one of first and second gate electrodes 13a1, 13b1 and a bottom surface formed of pad oxide film 4. LDD diffusion layers 15a and 15b are then formed in the surfaces of upper portions of semiconductor pillars 6a1 and 6b1 respectively by ion-implanting phosphorus into the entire surface of the resultant structure. Pad oxide film 4 is then removed by using a hydrofluoric-acid-containing solution so that the upper surfaces of LDD diffusion layers 15a and 15b are exposed. A silicon nitride film is then formed, for example, to a thickness of 10 nm on the entire surface of the resultant structure in the LPCVD process described above. The entire surface of the resultant structure is then etched back in a dry etching process to form second sidewall nitride film 16 on the sidewall of each of the openings. Stacked diffusion layers 17a and 17b, each of which is formed of a stacked single-crystal silicon layer, are then formed on the exposed upper surfaces of LDD diffusion layers 15a and 15b in a selective epitaxial growth process. LDD diffusion layer 15a and stacked silicon film 17a function as first upper diffusion layer 17c, and LDD diffusion layer 15b and stacked silicon film 17b function as second upper diffusion layer 17d.

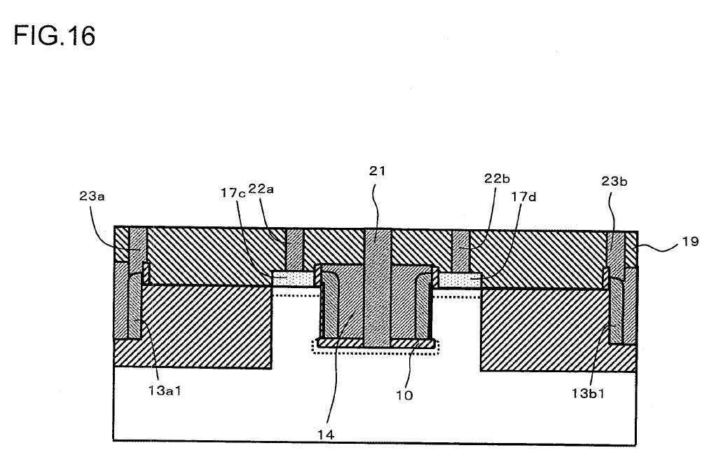

Second interlayer insulating film 19 is then formed on the entire surface of the resultant structure, as shown in FIG. 16. Thereafter, contact plug 21 to be connected to the first and second lower diffusion layers is formed through second interlayer insulating film 19, first interlayer insulating film 14, and lower oxide film 10. Contact plugs 22a and 22b to be connected to first and second upper diffusion layers 17c, 17d respectively are formed through second interlayer insulating film 19. Contact plugs 23a and 23b to be connected to first and second gate electrodes 13a1, 13b1 respectively are formed through second interlayer insulating film 19 and part of first interlayer insulating film 14. Contact plug 21 is shared by first vertical transistor Tr1 and second vertical transistor Tr2. After wiring lines 24 to be connected to the upper surfaces of the contact plugs are formed, first vertical transistor Tr1 and second vertical transistor Tr2 are formed, as shown in FIG. 11B.

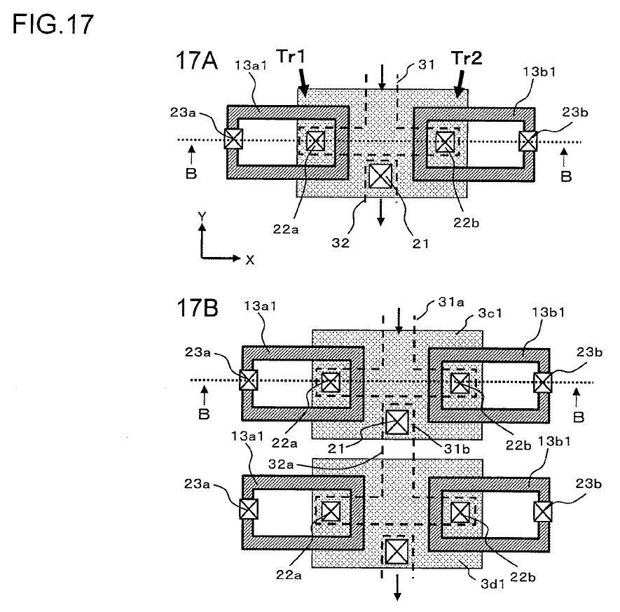

FIG. 17A shows an example of wiring arranged when Tr1 and Tr2, which form a pair of vertical transistors, are used as a parallel transistor. One input wiring line (first conductive material) 31 is split into two, which are connected to first and second upper diffusion layers 17c, 17d (not shown in FIG. 17A) of the transistors via contact plugs 22a and 22b, respectively. First upper diffusion layer 17c is connected to first and second lower diffusion layers 11 via first semiconductor pillar 6a1, and second upper diffusion layer 17d is connected to lower diffusion layers 11 via second semiconductor pillar 6b1. First and second lower diffusion layers 11 are connected to one output wiring line 32 via one contact plug 21. This parallel transistor is divided into two separate vertical transistors between one input wiring line 31 and one output wiring line (second conductive material) 32. If the two combined pillars are shifted in direction X as described above, the semiconductor pillars used as independent transistors suffer from variation in transistor characteristics because the semiconductor pillars have different widths. However, as shown in FIG. 17A, using two transistors Tr1 and Tr2 connected in parallel to each other as a single transistor always provides a fixed sum of the widths of first and second two semiconductor pillars 6a1, 6b1, that is, a fixed sum of the cross-sectional areas thereof, whereby stable transistor characteristics can be provided.

FIG. 17B shows an example in which the parallel transistor shown in FIG. 17A are provided in multiple stages serially connected to each other. In this case, one wiring line (first conductive material) 31a is split into two, which are connected to first and second upper diffusion layers 17c, 17d (not shown in FIG. 17B) of the transistors in first active region 3c1 via contact plugs 22a and 22b. First and second upper diffusion layers 17c, 17d are connected to first and second lower diffusion layers 11, respectively. First and second lower diffusion layers 11 are connected to one wiring line (second conductive material) 31 b via contact plug 21. Wiring line (first conductive material) 32a is split into two, which are connected to first and second upper diffusion layers 17c, 17d (not shown in FIG. 17B) of the transistors in second active region 3d1 via contact plugs 22a and 22b. Wiring line 31 b connects electrically to wiring line 32a. Parallel transistors provided in the following multiple active regions are serially connected to each other in the same manner. The parallel transistors can also be connected in parallel to each other. In FIGS. 17A and 17B, contact plug 21 is not present in cross-section B-B. In the example shown in FIGS. 17A and 17B, the cross-section B-B therefore has the structure shown in FIG. 16 but without contact plug 21.

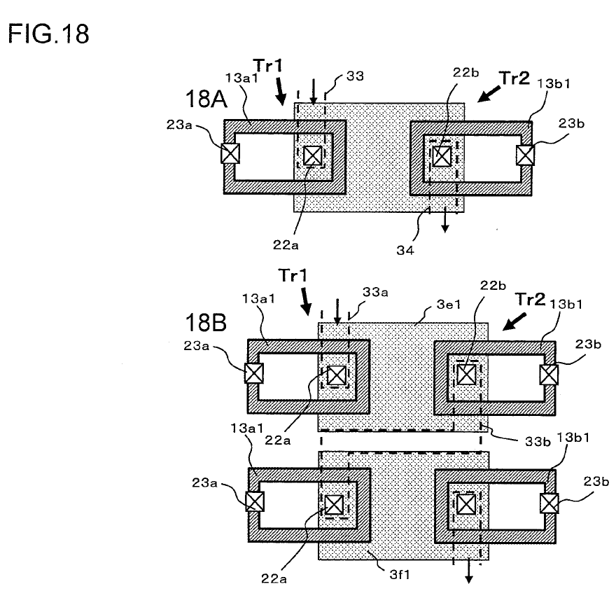

FIG. 18A shows an example of wiring arranged when a pair of vertical transistors Tr1 and Tr2 is used as a serial transistor. One input wiring line (first conductive material) 33 is connected to first upper diffusion layer 17c (not shown in FIG. 18A) of first vertical transistor Tr1 via contact plug 22a. First upper diffusion layer 17c is connected to first and second lower diffusion layers 11 via first semiconductor pillar 6a1 and then connected to contact plug 22b via second semiconductor pillar 6b1 which shares first and second lower diffusion layers 11 with first semiconductor pillar 6a1 and via second upper diffusion layer 17d (not shown in FIG. 18A). Contact plug 22b is connected to one output wiring line (first conductive material) 34. In this case, contact plug 21 is not required because first and second lower diffusion layers 11 themselves work as a contact between the two vertical transistors. Using two transistors Tr1 and Tr2 serially connected to each other as a single transistor as shown in FIG. 18A allows vertical transistors Tr1 and Tr2 to function in such a way that the difference in width between two semiconductor pillars 6a1 and 6b1, that is, difference in cross-sectional area therebetween is canceled out, whereby stable transistor characteristics can be provided. In the serial transistor, currents flowing through two transistors Tr1 and Tr2 flow in opposite directions, whereby more averaged transistor characteristics can be provided.

FIG. 18B shows an example in which the serial transistor shown in FIG. 18A are provided in multiple stages connected serially to each other. In this case, one wiring line (first conductive material) 33a is connected to first upper diffusion layer 17c (not shown in FIG. 18B) of first vertical transistor Tr1 in active region 3e1 via contact plug 22a above active region 3e1. First upper diffusion layer 17c is connected to first and second lower diffusion layers 11 and then connected to contact plug 22b via second vertical transistor Tr2, which shares first and second lower diffusion layers 11 with first vertical transistor Tr1. Contact plug 22b is connected to one wiring line (first conductive material) 33b. Wiring line 33b is connected to first upper diffusion layer 17c (not shown in FIG. 18B) of first vertical transistor Tr1 in active region 3f1 via contact plug 22a above active region 3f1. Serial transistors provided in the following multiple active regions are serially connected to each other in the same manner. The serial transistors can also be connected in parallel to each other.

In FIGS. 18A and 18B, wiring lines 33 and 34 are not split from one wiring line, and constitute an independent wiring line, respectively. That is, wiring lines 33 and 34 connect electrically to first and second upper diffusion layers 17c and 17d (not shown in FIGS. 18A and 18B), respectively.

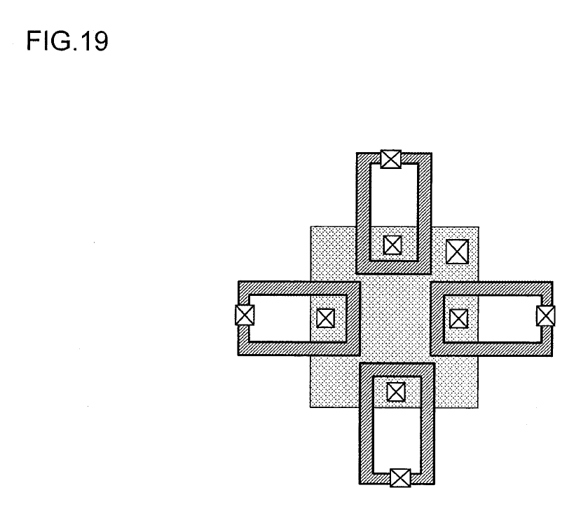

FIG. 19 shows an example in which two pairs of vertical transistors shown in FIGS. 11A and 11B are disposed along two lines perpendicular to each other in a single active region. In this example, two pairs of semiconductor pillars are disposed in the single active region, and two pairs of combined pillars including the two pairs of semiconductor pillars are formed. Further, two pairs of vertical transistors including the two pairs of semiconductor pillars are provided. In this case, a pair of vertical transistors can be used as a single vertical transistor, and hence two vertical transistors can be formed. Alternatively, a single parallel transistor formed of four vertical transistors can be provided. The above configuration is suitably used in a circuit that requires a larger amount of current. Alternatively, a single serial transistor formed of four vertical transistors can be provided. The configuration is suitably used in a circuit that requires a greater withstand voltage. FIG. 19 shows an example in which two pairs of vertical transistors are provided in a single active region, but the number of pairs is not limited to two. That is, as long as a single active region is large enough to accommodate semiconductor pillars, three or more pairs of vertical transistors each of which includes a pair of combined pillars extending in the same direction may be formed in the single active region.

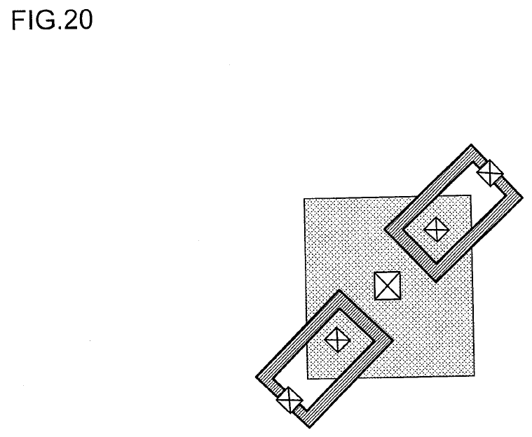

FIG. 20 shows an example in which a pair of vertical transistors is disposed in a region containing corners of a single active region.

The first transistor and the second transistor preferably face each other with approximate symmetry against a centerline that places the same distance from both of the first and second semiconductor pillars, as indicated by the arrangements shown FIGS. 11A and 11B, 18A and 18B, 19, and 20. Each of the arrangements described above, in which a pair of vertical transistors disposed in a single active region are connected serially or in parallel to each other, allows the transistors to function in such a way that the two combined pillars compensate for the effect of pattern shift. As a result, a single vertical transistor having stable characteristics can be provided.

Further, in each of the exemplary embodiments, as a contact plug connected to the first and second gate electrodes formed around the first and second combined pillars disposed in a single active region to each other, either a single contact plug common to the first and second gate electrodes or separate contact plugs for the first and second gate electrodes may be used.

### Third Exemplary Embodiment

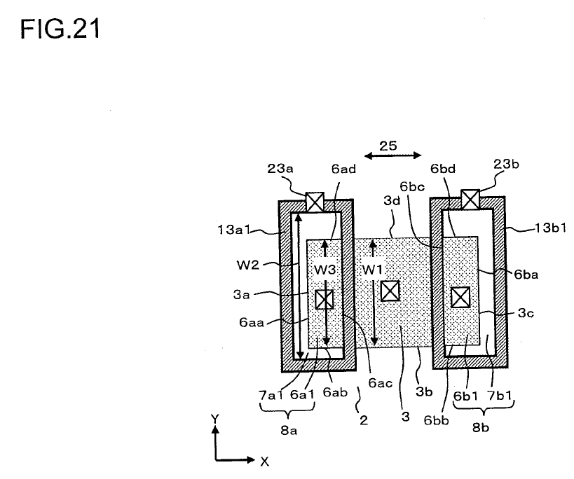

FIG. 21 shows a case similar to the aspect of the first exemplary embodiment which is shown in FIG. 1A but different therefrom in that width W3 of first and second semiconductor pillars 6a1, 6b1 in direction Y (direction perpendicular to direction 25 in which each combined pillar extends) is equal to width W1 of active region 3 in direction Y. Active region 3 includes side surfaces 3a and 3c facing each other in direction X and side surfaces 3b and 3d facing each other in direction Y, as in the first exemplary embodiment. First combined pillar 8a is a combination of first semiconductor pillar 6a1, which is in contact with one side surface 3a of active region 3, and first insulator pillar 7a1. First semiconductor pillar 6a1 includes side surfaces 6aa and 6ac facing each other in direction X and side surfaces 6ab and 6ad facing each other in direction Y. Side surface 6aa coincides with one side surface 3a of active region 3. Side surfaces 6ab and 6ad facing each other in direction Y overlap with side surfaces 3b and 3d of active region 3. In the exemplary embodiment, maximum width W2 of first insulator pillar 7a1 in direction Y is greater than width W3 of first semiconductor pillar 6a1 in direction Y. Three side surfaces 6a a, 6ab, and 6ad of first semiconductor pillar 6a1 are therefore in contact with first insulator pillar 7a1. First gate electrode 13a1 covers circumferential side surfaces of first combined pillar 8a. In the arrangement, first semiconductor pillar 6a1 faces first gate electrode 13a1 via only one side surface formed of side surface 6ac with a first gate insulator (not shown) interposed therebetween. Thus configured first combined pillar 8a is horizontally reversed so that second combined pillar 8b is disposed along side surface 3c of the active region, which faces side surface 3a. A pair of vertical transistors are thus formed.

In this configuration as well, contact plugs 23a and 23b, which feed electric power to the gate electrodes, are formed along circumferential sidewalls of first and second insulator pillars 7a1, 7b1 in isolation region 2. As a result, it is possible to prevent contact plugs 23a, 23b and semiconductor substrate 1 (lower diffusion layers) from forming short circuit.

In the exemplary embodiment, first gate electrode 13a1 is disposed along only one side surface of first semiconductor pillar 6a1 and second gate electrode 13b1 is disposed along only one side surface of second semiconductor pillar 6b1. The configuration described above is effective to a case where widths W4 and W5 of the first and second semiconductor pillars in direction X shown in FIG. 11A are reduced to be narrower than width W3 thereof in direction Y. That is, widths W4 and W5 in direction X represent the thicknesses of first and second semiconductor pillars 6a1, 6b1, each of which forms a channel of a transistor, and a decrease in W4 and W5 means that the thickness of each channel region decreases. The transistor characteristics can therefore be readily controlled even when each of first and second gate electrodes 13a1, 13b1 is formed along only one side surface.

### Fourth Exemplary Embodiment

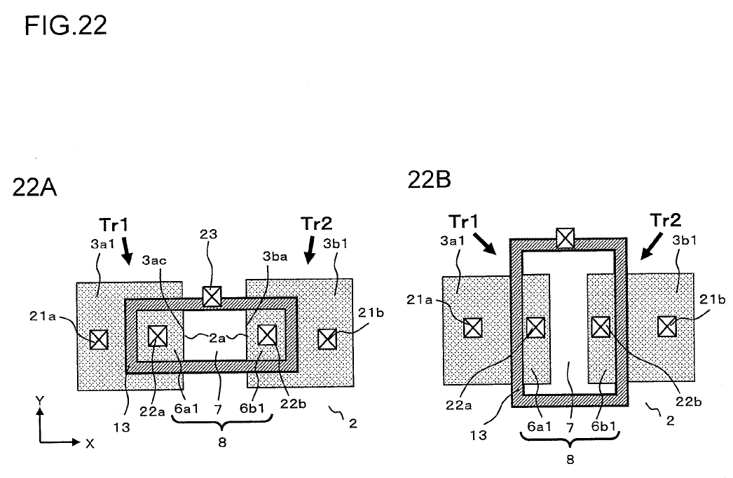

FIGS. 22A and 22B show the configuration of combined pillar 8 based on two active regions 3a1 and 3b1 that sandwich isolation region 2 and formed of first and second two semiconductor pillars 6a1, 6b1 that share central insulator pillar 7 and are located on opposite sides thereof. The other basic configurations are the same as those shown in FIGS. 1A to 1D, and no redundant description of the same portions will therefore be made.

First active region 3a1 and second active region 3b1, which sandwich isolation region 2, are provided, and one side surface 3ac of first active region 3a1 and one side surface 3ba of second active region 3b1 are disposed to face each other. First semiconductor pillar 6a1 is disposed in first active region 3a1 and in contact with one side surface 3ac thereof. First upper diffusion layer (not shown in FIGS. 22A and 22B) is disposed in upper portion of first semiconductor pillar 6a1. First lower diffusion layer (not shown in FIGS. 22A and 22B) is disposed in lower portion of first active region 3a1. Second semiconductor pillar 6b1 is disposed in second active region 3b1 and in contact with one side surface 3ba thereof, which faces one side surface 3ac of first active region 3a1. Second upper diffusion layer (not shown in FIGS. 22A and 22B) is disposed in upper portion of second semiconductor pillar 6b1. Second lower diffusion layer (not shown in FIGS. 22A and 22B) is disposed in lower portion of second active region 3b1. First and second upper diffusion layers are electrically connected to one common wiring line (first conductive material; not shown in FIGS. 22A and 22B) or two independent wiring lines (first conductive material; not shown in FIGS. 22A and 22B). First and second lower diffusion layers are electrically connected to one common wiring line (second conductive material; not shown in FIGS. 22A and 22B).

Further, insulator pillar 7 is located between first active region 3a1 and second active region 3b1 and includes one end in direction X in contact with one side surface 3ac of first active region 3a1 and the other end in contact with one side surface 3ba of second active region 3b1. That is, the two side surfaces of insulator pillar 7 are in contact with side surfaces of first and second semiconductor pillars 6a1, 6b1 via sidewall 2a of the trench in which insulator pillar 7 is formed. First semiconductor pillar 6a1, insulator pillar 7, second semiconductor pillar 6b1 are combined into single combined pillar 8. That is, combined pillar 8 has a configuration in which shared insulator pillar 7 is located at the center and first and second two semiconductor pillars 6a1, 6b1 are disposed on opposite sides of insulator pillar 7. Gate electrode 13 is disposed on the circumferential side surfaces of single combined pillar 8. Single contact plug 23, which feeds electric power to the gate electrode, is provided along gate electrode 13 located on a circumferential side surface of shared insulator pillar 7.

In the thus disposed first and second two vertical transistors Tr1 and Tr2, in which contact plug 23, which feeds electric power to the gate, is formed along a circumferential sidewall of shared insulator pillar 7 in isolation region 2. Therefore, it is possible to prevent contact plug 23 and semiconductor substrate 1 (lower diffusion layer) from forming short circuit as in the configurations described above. Further, two vertical transistors Tr1 and Tr2 connected serially or in parallel to each other, whereby they can function in such a way that the two combined pillars can compensate for the effect of pattern shift and work as a single vertical transistor having stable characteristics. FIGS. 22A and 22B show the case where a pair of vertical transistors Tr1 and Tr2 are provided in two active regions 3a1 and 3b1, but the number of active regions and transistors is not limited to two. For example, there may be formed combined pillars, which include three or more semiconductor pillars provided in three or more active regions respectively and insulator pillars provided between the semiconductor pillars. Three or more transistors in which the insulator pillars are shared may then be formed by providing a gate electrode that covers the circumference of each of the combined pillars.

FIG. 22B shows an exemplary configuration in which the exemplary embodiment reflects the aspect of the third exemplary embodiment shown in FIG. 21.

Gate electrode 13 in the exemplary embodiment is shared by vertical transistors Tr1 and Tr2 provided in first and second two active regions 3a1, 3b1 adjacent to each other with isolation region 2 interposed therebetween, as shown in FIGS. 22A and 22B. In other words, gate electrode 13 is allowed to function as a wiring line that connects the two semiconductor devices to each other. That is, insulator pillar 7 is disposed also in isolation region 2 located between first active region 3a1 and second active region 3b1, whereby gate electrode 13 formed along two side surfaces of insulator pillar 7 that face each other can be used as a wiring line that connects the semiconductor device provided in first active region 3a1 and the semiconductor device provided in second active region 3b1 to each other. By forming gate electrode 13 in an etch back process, it is formed on the side surfaces of insulator pillar 7 in a self-aligned manner. Lithography-based patterning for wiring is therefore not required, and the plan-view width of gate electrode 13 can be controlled by controlling the film thickness at the time of film formation. As a result, gate electrode 13 can be formed to be narrower than the widths of first and second semiconductor pillars 6a1, 6b1 and insulator pillar 7, which are formed in a process that provides a minimum dimension. Further, since gate electrode 13 is formed on the side surfaces of insulator pillar 7 in a self-aligned manner as described above, gate electrode 13 can be formed around insulator pillar 7 having any plan-view shape. That is, active regions 3a1 and 3b1, which are disposed along a straight line in direction X in FIG. 22A so that insulator pillar 7 has a rectangular plan-view shape. Even when active regions 3a1 and 3b1 are shifted from each other in direction Y, semiconductor devices formed in active regions 3a1 and 3b1 can be connected to each other with a wiring line formed of gate electrode 13 by using bent insulator pillar 7. That is, even if a plurality of active regions 3a1 and 3b1 are arranged in an arbitrary manner, a plurality of semiconductor devices can be connected to each other with a wiring line formed of gate electrode 13 by disposing insulator pillar 7 between the plurality of active regions 3a1 and 3b1.

### Fifth Exemplary Embodiment

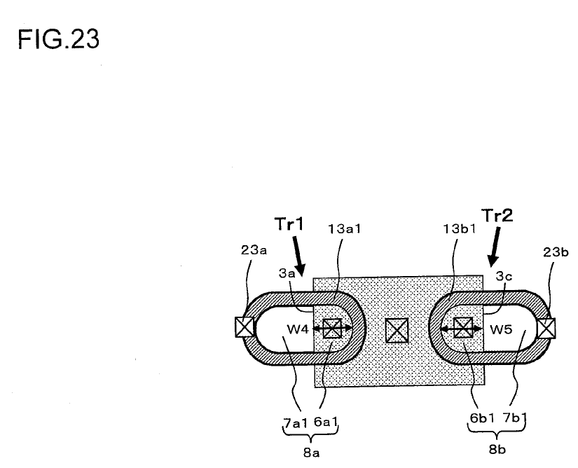

FIG. 23 shows the configuration of a fifth exemplary embodiment. In the second exemplary embodiment, FIGS. 11A and 11B show combined pillars 8a and 8b, each of which has a rectangular shape in a plan view, whereas in the exemplary embodiment, each of first and second combined pillars 8a, 8b has a circular shape in a plan view. Even when each of first and second combined pillars 8a, 8b has a circular shape in a plan view as in the exemplary embodiment, the same advantageous effect as that provided in the second exemplary embodiment can be provided. That is, contact plugs 23a and 23b, which feed electric power to the gate electrodes, are provided in portions that overlap with first and second gate electrodes 13a1, 13b1, which are located around the circumferential side surfaces of first and second insulator pillars 7a1, 7b1 formed in isolation region 2. It is possible to prevent contact plugs 23a and 23b, which feed electric power to the gate electrodes, and the silicon substrate (lower diffusion layers) from forming short circuit. Further, first semiconductor pillar 6a1, which forms first vertical transistor Tr1, is provided in active region 3 and in contact with side surface 3a thereof, and second semiconductor pillar 6b1, which forms second vertical transistor Tr2, is provided in the same active region 3 and in contact with side surface 3c thereof, which faces side surface 3a. Therefore, even if pattern shift occurs in direction X relative to active regions 3 when combined pillars 8a and 8b are formed, the sum of width W4 of first semiconductor pillar 6a in direction X (direction 25 in which combined pillar extends) and width W5 of second semiconductor pillar 6b in direction X can always be maintained at a fixed value. As a result, using first vertical transistor Tr1 and second vertical transistor Tr2 connected serially or in parallel to each other as a single vertical transistor allows the single vertical transistor to always have a fixed sum of the widths of semiconductor pillars.

As described above, according to the exemplary embodiments, the reliability of a vertical transistor can be improved because no short circuit occurs between a contact plug that feeds electric power to a gate electrode and a lower diffusion layer. Further, using two vertical transistors connected serially or in parallel to each other as a single vertical transistor can provide more stable transistor characteristics. The plurality of above exemplary embodiments have been described with reference to the case where a combined pillar has a rectangular shape, and a combined pillar having an elliptical shape shown in FIG. 23 can provide the same advantageous effects as those provided in the exemplary embodiments described above.

In FIGS. 11A and 11B and the following figures, two transistors are called as follows: The left transistor is called a first vertical transistor; and the right transistor is called a second vertical transistor. It is, however, noted that the first and second vertical transistors are named as described above for convenience in FIGS. 11A and 11B and the following figures, and the right transistor may be called a first vertical transistor and the left transistor may be called a second vertical transistor. Further, in each of the figures, corresponding portions may be hatched differently between a plan view and a cross-sectional view in some cases.

In FIGS. 17A, 17B, 18A, 18B, 21 and 23, first and second gate electrodes 13a1 and 13b1 may be electrically connected to one common wiring line (third conductive material; not shown in FIGS. 17A, 17B, 18A, 18B, 21 and 23) or two independent wiring lines (third conductive material; not shown in FIGS. 17A, 17B, 18A, 18B, 21 and 23) via contact plugs 23a and 23b, respectively.

In the exemplary embodiments described above, contact plug or wiring line, that is electrically connected to upper diffusion layer, is referred to as “first conductive material”. Contact plug or wiring line, that is electrically connected to lower diffusion layer, is referred to as “second conductive material”. Contact plug or wiring line, that is electrically connected to gate electrode, is referred to as “third conductive material”.

As shown in the exemplary embodiments described above, to allow a device to function as a transistor, a gate electrode needs to be formed on at least one side surface of a semiconductor pillar with a gate insulator interposed therebetween.

It is apparent that the present invention is not limited to the above embodiments, but may be modified and changed without departing from the scope and spirit of the invention.

What is claimed is:

1. A semiconductor device comprising:
an isolation region formed by filling a trench with an insulator, the trench having a sidewall in a semiconductor substrate;
an active region surrounded with the sidewall of the trench;
a combined pillar including a semiconductor pillar in the active region and an insulator pillar in the isolation region, the insulator pillar contacting the semiconductor pillar with the sidewall of the trench interposed therebetween;
a gate electrode covering a side surface surrounding the combined pillar; and
a transistor including the combined pillar and the gate electrode.

2. The semiconductor device according to claim 1,
wherein the transistor further comprises:
an upper diffusion layer being disposed in an upper portion of the semiconductor pillar; and
a lower diffusion layer being disposed in a lower portion of the active region.

3. The semiconductor device according to claim 2,
wherein the transistor further comprises a gate insulator that is sandwiched between the gate electrode and the semiconductor pillar.

4. The semiconductor device according to claim 3, further comprising:
a first conductive material connecting electrically to the upper diffusion layer;
a second conductive material connecting electrically to the lower diffusion layer; and
a third conductive material connecting electrically to the gate electrode.

5. A semiconductor device comprising:
an isolation region formed by filling a trench with an insulator, the trench having a sidewall in a semiconductor substrate;
an active region surrounded with the sidewall of the trench;
a first combined pillar including a first semiconductor pillar in the active region and a first insulator pillar in the isolation region, the first insulator pillar contacting the first semiconductor pillar with the sidewall of the trench interposed therebetween;
a first gate electrode covering a side surface surrounding the first combined pillar;
a first transistor including the first combined pillar and the first gate electrode;
a second combined pillar including a second semiconductor pillar in the active region and a second insulator pillar in the isolation region, the second insulator pillar contacting the second semiconductor pillar with the sidewall of the trench interposed therebetween;
a second gate electrode covering a side surface surrounding the second combined pillar; and
a second transistor including the second combined pillar and the second gate electrode,
wherein the first transistor and the second transistor face each other with approximate symmetry against a centerline that places a same distance from both of the first and second semiconductor pillars.

6. The semiconductor device according to claim 5,
wherein a plurality of pairs of the first and second transistors are disposed in one active region.

7. The semiconductor device according to claim 5,
wherein the first transistor further comprises:
a first upper diffusion layer being disposed in an upper portion of the first semiconductor pillar; and
a first lower diffusion layer being disposed in a lower portion of the active region,
wherein the second transistor further comprises:
a second upper diffusion layer being disposed in an upper portion of the second semiconductor pillar; and
a second lower diffusion layer being disposed in a lower portion of the active region, and
wherein the first and second lower diffusion layers are combined with each other.

8. The semiconductor device according to claim 7,
wherein the first transistor further comprises:
a first gate insulator that is sandwiched between the first gate electrode and the first semiconductor pillar, and
wherein the second transistor further comprises:
a second gate insulator that is sandwiched between the second gate electrode and the second semiconductor pillar.

9. The semiconductor device according to claim 8, further comprising:
one first conductive material connecting electrically to both the first and second upper diffusion layers; and
one second conductive material connecting electrically to both the first and second lower diffusion layers.

10. The semiconductor device according to claim 8, further comprising:
two first conductive materials connecting electrically to the first and second upper diffusion layers, respectively.

11. The semiconductor device according to claim 8,
wherein the semiconductor device comprises:
a first active region including the first and second lower diffusion layers;
a second active region including the first and second upper diffusion layers;
one second conductive material connecting electrically to the first and second lower diffusion layers in the first active region; and
one first conductive material connecting electrically to the first and second upper diffusion layers in the second active region, and
wherein the one second conductive material connects electrically to the one first conductive material.

12. The semiconductor device according to claim 9, further comprising:
one third conductive material connecting electrically to both the first and second gate electrodes.

13. The semiconductor device according to claim 9, further comprising:
two third conductive materials connecting electrically to the first and second gate electrodes, respectively.

14. The semiconductor device according to claim 10, further comprising:
one third conductive material connecting electrically to both the first and second gate electrodes.

15. The semiconductor device according to claim 10, further comprising:
two third conductive materials connecting electrically to the first and second gate electrodes, respectively.

16. A semiconductor device comprising:
an isolation region formed by filling a trench with an insulator, the trench having a sidewall in a semiconductor substrate;
a first active region surrounded with the sidewall of the trench;
a second active region surrounded with the sidewall of the trench;
a combined pillar including a first semiconductor pillar in the first active region, a second semiconductor pillar in the second active region, and an insulator pillar in the isolation region that is provided between the first and second semiconductor pillars;
a gate electrode covering a side surface surrounding the combined pillar; and
a transistor including the combined pillar and the gate electrode,
wherein both sides of the insulator pillar contact each of the first and second semiconductor pillars with the sidewall of the trench interposed therebetween.

17. The semiconductor device according to claim 16, further comprising:
a first upper diffusion layer being disposed in an upper portion of the first semiconductor pillar;
a second upper diffusion layer being disposed in an upper portion of the second semiconductor pillar;
a first lower diffusion layer being disposed in a lower portion of the first active region; and
a second lower diffusion layer being disposed in a lower portion of the second active region.

18. The semiconductor device according to claim 17, further comprising:
a gate insulator that is sandwiched between the gate electrode and each of the first and second semiconductor pillars.

19. The semiconductor device according to claim 18, further comprising:
one first conductive material connecting electrically to both the first and second upper diffusion layers;
one second conductive material connecting electrically to both the first and second lower diffusion layers; and
a third conductive material connecting electrically to the gate electrode.

20. The semiconductor device according to claim 18, further comprising:
two first conductive materials connecting electrically to the first and second upper diffusion layers, respectively,
one second conductive material connecting electrically to both the first and second lower diffusion layers; and
a third conductive material connecting electrically to the gate electrode.
